(19) United States
(12) Patent Application Publication
(10) Pub. No.: US 2026/0347991 A1
(43) Pub. Date: Nov. 5, 2026

(54) HIGH-PRESSURE SUBSTRATE PROCESSING APPARATUS

(71) Applicant: HPSP Co., Ltd., Hwaseong-si, Gyeonggi-do (KR)

(72) Inventors: Kunyoung LIM, Hwaseong-si, Gyeonggi-do (KR); Jae Beom AHN, Hwaseong-si, Gyeonggi-do (KR)

(21) Appl. No.: 19/486,117

(22) PCT Filed: May 17, 2024
(86) PCT No.: PCT/KR2024/095822

§ 371 Date: Nov. 20, 2025

(30) Foreign Application Priority Data
May 22, 2023 (KR) 10-2023-0065806

(51) Int. Cl. C23C 8/06

(52) U.S. Cl. CPC C23C 8/06

(57) ABSTRACT

The present invention provides a high-pressure substrate processing apparatus including: an inner chamber configured to accommodate a substrate to be processed and a reaction gas supplied at a first pressure higher than atmospheric pressure; an outer chamber including an outer housing that accommodates the inner chamber, and an outer door configured to move between a closed state in which the outer housing is closed and an opened state in which the outer housing is opened, and configured to accommodate a protection gas supplied at a second pressure that is set relative to the first pressure; and a fastening module including a support protrusion installed on the outer housing, a rotary member rotatably installed on the outer door, and a locking protrusion protruding from the rotary member and disposed on the support protrusion as the rotary member rotates in the closed state.

### TECHNICAL FIELD

The present disclosure relates to a processing apparatus used to process a substrate in a high-pressure environment.

### BACKGROUND ART

Generally, during the semiconductor device manufacturing process, various types of processing are performed on a semiconductor substrate. Examples of these processes include oxidation, nitridation, silicide, ion implantation, deposition processes, etc. A hydrogen or deuterium heat treatment process is also used to improve the interface characteristics of the semiconductor device.

The gas used to process the substrate is supplied to the chamber at high pressure and acts on the semiconductor substrate. To maintain the chamber at high pressure, the housing of the chamber should be securely closed by a door.

When a closed state of the chamber is loosened by high-pressure gas, a gap may be formed between the housing and the door. The gap may become a passage through which the gas within the chamber leaks out.

The above-described background art is technical information retained by the inventor to derive the embodiments of the present disclosure or acquired by the inventor while deriving the present disclosure, and thus should not be construed as art that was publicly known prior to the filing date of the present disclosure.

### DISCLOSURE

### Technical Problem

The present disclosure is to provide a high-pressure substrate processing apparatus that may firmly maintain a closed state between a housing and a door even under high pressure within a chamber.

In addition, the present disclosure provides a high-pressure substrate processing apparatus capable of minimizing a force required for fastening between the housing and the door.

### Technical Solution

According to an aspect of the present disclosure, a high-pressure processing apparatus includes: an inner chamber configured to accommodate a substrate to be processed and a reaction gas supplied at a first pressure higher than atmospheric pressure; an outer chamber including an outer housing that accommodates the inner chamber, and an outer door configured to move between a closed state in which the outer housing is closed and an opened state in which the outer housing is opened, and configured to accommodate a protection gas supplied at a second pressure that is set relative to the first pressure; and a fastening module including a support protrusion installed on the outer housing, a rotary member rotatably installed on the outer door, and a locking protrusion protruding from the rotary member and disposed on the support protrusion as the rotary member rotates while the outdoor is in the closed state.

The rotary member may be disposed within an area defined by the outer housing.

The rotary member may include a rotating ring having a ring shape.

According to another aspect of the present disclosure, a high-pressure processing apparatus includes: an inner chamber configured to accommodate a substrate to be processed and a reaction gas supplied at a first pressure higher than atmospheric pressure; an outer chamber including an outer housing that accommodates the inner chamber, and an outer door configured to move between a closed state in which the outer housing is closed and an opened state in which the outer housing is opened, and configured to accommodate a protection gas supplied at a second pressure that is set relative to the first pressure; and a fastening module including a support protrusion installed on the outer housing and a locking protrusion disposed on the support protrusion while being connected to the outer door as the locking protrusion moves in the closed state, in which the outer door includes an upper plate that contacts the outer housing in the closed state, and the locking protrusion is disposed below the upper plate.

The outer door may further include a lower plate disposed at a different level from the upper plate, and the locking protrusion may be disposed between the upper plate and the lower plate.

The locking protrusion may include one of an upper portion disposed to correspond to a side surface of the upper plate; and a lower portion disposed to correspond to a side surface of the lower plate.

The outer door may further include a seal member that contacts the outer housing in the closed state, and the locking protrusion may be configured to rotate independently of contact between the seal member and the outer housing.

The fastening module may further include a drive unit configured to rotate the locking protrusion.

The fastening module may further include a rotary member having the locking protrusion formed thereon, and the drive unit may be configured to rotate the rotary member around a rotational axis extending along an opening/closing direction of the outer door.

The drive unit may include: a driven gear provided on the rotary member; a driving gear meshing with the driven gear; and a motor rotating the driving gear.

According to still another aspect of the present disclosure, a high-pressure processing apparatus includes: a chamber including a housing configured to accommodate a substrate to be processed and a process gas supplied at a pressure higher than atmospheric pressure, and a door configured to move between a closed state in which the housing is closed and an opened state in which the housing is opened; a fastening module including a support protrusion installed on the housing and a locking protrusion disposed on the support protrusion while being connected to the door as the locking protrusion moves in the closed state, in which the door includes an upper plate that contacts the housing in the closed state, and the locking protrusion is disposed below the upper plate.

The door may further include a lower plate disposed at a different level from the upper plate, and the locking protrusion may be disposed between the upper plate and the lower plate.

The fastening module may further include a rotary member that is rotatably installed on the door and has the locking protrusion protruding therefrom, and the locking protrusion may be supported by the support protrusion as the rotary member rotates.

The door may further include a seal member installed on the upper plate, and the locking protrusion may be configured to move independently of contact between the housing and the seal member in the closed state.

The process gas may include a reaction gas containing an active gas and a protection gas that is an inert gas, and the housing may include: an inner housing configured to accommodate the substrate to be processed and the reaction gas; and an outer housing that accommodates the inner housing and is coupled to the inner housing to form a closed space that accommodates the protection gas together with the inner housing, and the door may be configured to close the inner housing.

### Advantageous Effects

According to the high-pressure substrate processing apparatus of the present disclosure configured as described above, by maintaining a housing and a door that accommodate a substrate and a high-pressure gas, in a fastened state by a fastening module and by configuring the fastening module such that a locking protrusion moves with respect to an outer door to be disposed on a support protrusion installed on the housing, it is possible to firmly maintain the closed state between the housing and the door even under a high pressure within a chamber due to the fastening between the locking protrusion and the support protrusion.

In addition, since the locking protrusion moves independently of the door, to fasten the housing and the door, only the locking protrusion, excluding the door, needs to move. As a result, it is possible to minimize the power required for fastening between the housing and the door.

### BRIEF DESCRIPTION OF THE DRAWINGS

FIG. 1 is a conceptual diagram of a high-pressure substrate processing apparatus 100 according to an embodiment of the present disclosure.

FIG. 2 is an exploded perspective view illustrating an opened state of the high-pressure substrate processing apparatus 100 of FIG. 1.

FIG. 3 is a cross-sectional view illustrating a closed state of the high-pressure substrate processing apparatus 100 of FIG. 2.

FIG. 4 is a cutaway perspective view illustrating a configuration for driving a rotating ring 157 of FIG. 3.

FIG. 5 is a cross-sectional view illustrating a main portion of a high-pressure substrate processing apparatus 100′ according to one modified example of the high-pressure substrate processing apparatus 100 of FIG. 3.

FIG. 6 is a cross-sectional view illustrating a main portion of a high-pressure substrate processing apparatus 100″ according to another modified example of the high-pressure substrate processing apparatus 100 of FIG. 3.

FIG. 7 is a cross-sectional view illustrating a closed state of a high-pressure substrate processing apparatus 200 according to another embodiment of the present disclosure.

### BEST MODE

Hereinafter, exemplary embodiments of the present disclosure will be described in detail with reference to the accompanying drawings.

The present disclosure is not limited to exemplary embodiments set forth herein, but may be modified in various different forms. However, the present embodiment is provided solely to ensure that the disclosure of the present disclosure is complete and to fully inform those skilled in the art of the scope of the invention. Therefore, the present disclosure is not limited to the embodiments disclosed below, but should be understood to encompass all modifications, equivalents, and substitutions within the teachings and scope of the present disclosure, including substitutions or additions of components of one embodiment with those of another.

It should be understood that the accompanying drawings are provided only in order to allow embodiments disclosed in the present specification to be easily understood, and the teachings disclosed in the present specification are not limited by the accompanying drawings, but includes all the modifications, equivalents, and substitutions included in the teachings and the scope of the present disclosure. In the drawings, components may be exaggerated in size or thickness for ease of understanding, but this should not be construed as limiting the scope of protection of the present disclosure.

Terms used in the present specification are used only in order to describe specific implementation examples or embodiments rather than limiting the present disclosure. Singular expressions are intended to include plural expressions unless the context clearly indicates otherwise. In the specification, terms such as “~comprising,” or “~consisting of” are intended to specify the presence of stated features, numbers, steps, operations, components, parts, or combinations thereof described in the specification. That is, it should be understood that terms such as “~including” or “~consisting of” in the specification do not preclude the existence or addition possibility of one or more other features or numbers, steps, operations, components, parts, or combinations thereof.

Terms including ordinal numbers such as “first”, “second”, etc., may be used to describe various components, but the components are not to be construed as being limited to the terms. The terms are used to distinguish one component from another component.

It is to be understood that when one element is referred to as being “connected to” or “coupled to” another element, it may be connected directly to or coupled directly to another element or be connected to or coupled to another element, having the other element intervening therebetween. On the other hand, it should be understood that when one element is referred to as being “connected directly to” or “coupled directly to” another element, it may be connected to or coupled to another element without the other element interposed therebetween.

When a component is referred to as being “above” or “below” another component, it should be understood that it is not only positioned directly above that other component, but also that other components may be present in between.

Unless indicated otherwise, it is to be understood that all the terms used in the specification including technical and scientific terms have the same meaning as those that are generally understood by those who skilled in the art. Terms generally used and defined by a dictionary should be interpreted as having the same meanings as meanings within a context of the related art and should not be interpreted as having ideal or excessively formal meanings unless being clearly defined otherwise in the present specification.

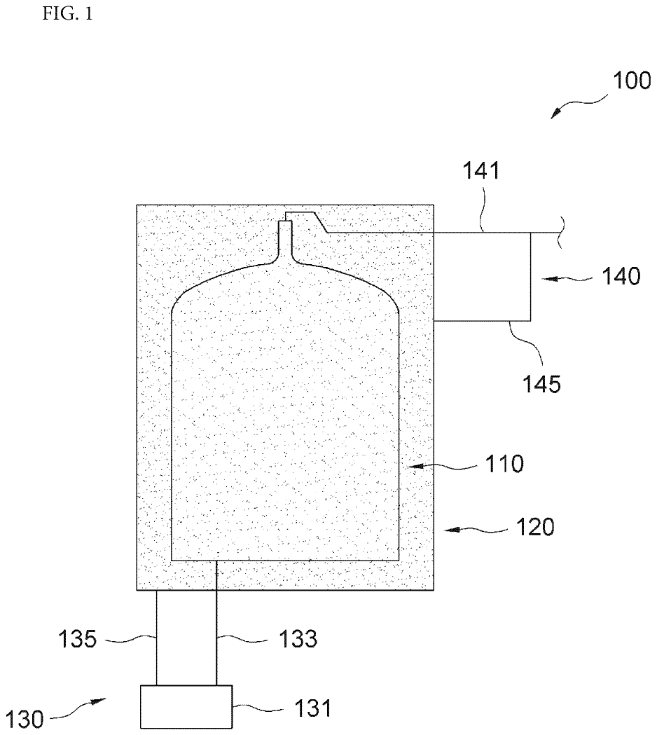

FIG. 1 is a conceptual diagram of a high-pressure substrate processing apparatus 100 according to an embodiment of the present disclosure.

Referring to this drawing, a high-pressure substrate processing apparatus 100 may include an inner chamber 110, an outer chamber 120, a gas supply module 130, and a gas exhaust module 140.

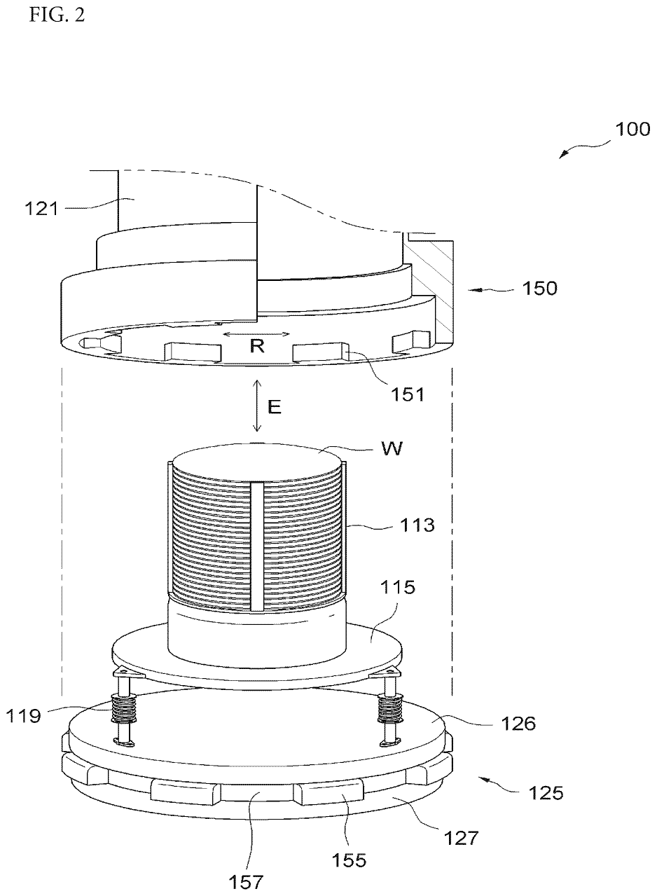

The inner chamber 110 forms a processing space that accommodates an object to be processed. The inner chamber 110 may be manufactured from a non-metallic material, such as quartz, to reduce contamination in a high-temperature and high-pressure operating environment. Depending on an operation of a heater (not illustrated) disposed on an outer side of the inner chamber 110, the temperature of the inner chamber 110 may reach several hundred to a thousand °C. The object may be, for example, a semiconductor substrate W (see FIG. 2) loaded onto a holder. The holder may be a wafer boat 113 (see FIG. 2) capable of loading a substrate W to be processed in multiple layers.

The outer chamber 120 forms an inner space that accommodates the inner chamber 110. The outer chamber 120 is disposed outside the inner chamber 110. Unlike the inner chamber 110, the outer chamber 120 is free from concerns about contamination of the object and may therefore be made of metal.

The gas supply module 130 is configured to supply gas to the inner chamber 110 and the outer chamber 120. The gas supply module 130 has a gas supply device 131 that serves as a gas source. The gas supply device 131 may selectively supply, to the inner chamber 110, reaction gases, such as hydrogen gas (H₂), deuterium gas (D₂), fluorine gas (F₂), ammonia gas (NH₃), chlorine gas (Cl₂), and nitrogen gas (N₂) as a reaction gas for a heat treatment process. The gas supply device 131 may provide, to the outer chamber 120, a protection gas, such as nitrogen gas or argon gas (Ar) that is an inert gas. The reaction gas and the protection gas may be simply referred to as process gases. The process gases are supplied to the inner chamber 110 or outer chamber 120 via a reaction gas line 133 or a protection gas line 135, respectively. The protection gas supplied to the outer chamber 120 is specifically supplied to a space (protection space) between the outer chamber 120 and the inner chamber 110.

The process gas may be supplied to form a pressure (high pressure) higher than atmospheric pressure, for example, a pressure ranging from a few to tens of atm. When the pressure of the reaction gas is a first pressure and the pressure of the protection gas is a second pressure, these pressures may be maintained at a set relationship. For example, the second pressure may be set to be slightly higher than the first pressure. Such a pressure difference provides the advantage of preventing the reaction gas from leaking from the inner chamber 110.

The gas exhaust module 140 is configured to exhaust the process gas. In order to exhaust the reaction gas from the inner chamber 110, an exhaust pipe 141 is connected to an upper portion of the inner chamber 110. Similarly, to exhaust the protection gas from the outer chamber 120, an exhaust pipe 145 communicating with the outer chamber 120 may be provided. Since these exhaust pipes 141 and 145 are integrated into one, the reaction gas is diluted by the protection gas during the exhaust process, and thus, the concentration of the reaction gas is lowered.

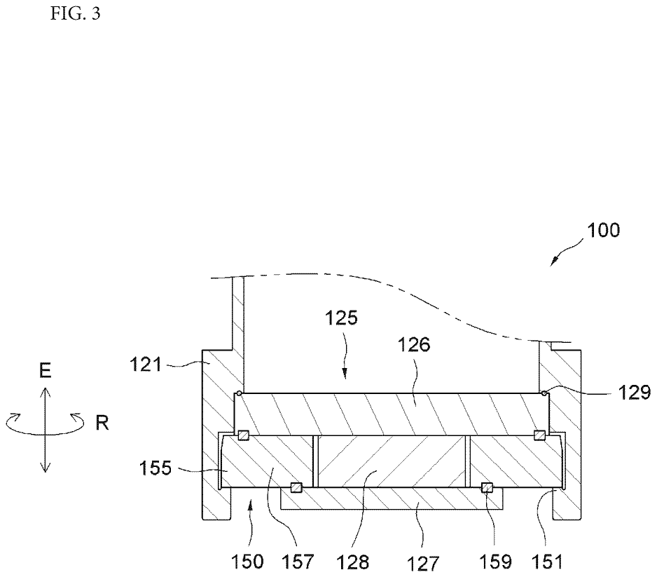

The fastening structure of the outer chamber 120 will be described with reference to FIGS. 2 and 3. FIG. 2 is an exploded perspective view illustrating an opened state of the high-pressure substrate processing apparatus 100 of FIG. 1, and FIG. 3 is a cross-sectional view illustrating a closed state of the high-pressure substrate processing apparatus 100 of FIG. 2.

Referring to these drawings, the inner chamber 110 includes the inner housing (not illustrated) and the inner door 115. The inner housing forms the processing space that accommodates the substrate W to be processed, and its lower portion may have an opened form. The inner door 115 has a form in which the opened lower portion of the inner housing is closed. The inner door 115 may have a trough shape in which it is opened downward overall.

As the inner door 115 is lowered, the processing space is opened (opened state, see FIG. 2). In the opened state, the substrate to be processed is unloaded from the boat 113, and a new substrate to be processed is loaded onto the boat 113. As the inner door 115 is raised, the processing space is closed (closed state, see FIG. 3). In the closed state, processing, such as heat treatment or deposition, is performed on the substrate W to be processed.

The outer chamber 120 also includes the outer housing 121 and the outer door 125. The outer housing 121 is sized to accommodate the inner chamber 110. The inner housing (not illustrated) is mounted on the outer housing 121. The outer door 125 may also move to open and close the outer housing 121. The outer door 125 may be connected to the inner door 115 by a support member 119. The support member 119 may have a spring support structure that elastically is expanded and contracted along an opening/closing direction E. The opening/closing direction E is a direction in which the outer door 125 moves to transition between the closed state and the opened state. When the outer housing 121 is erected, the opening/closing direction E may be substantially the same as the elevation or vertical direction. During the transition from the opened state to the closed state, the support member 119 allows the outer door 125 to move toward the inner door 115. In an alternative embodiment, the support member 119 may be, for example, an O-ring. In another embodiment, the inner door 115 and the outer door 125 may be integrated to form a single member.

The outer door 125 opens and closes the outer housing 121 while moving up and down together with the inner door 115. Unlike the above description, the inner door 115 and the outer door 125 are not connected to each other and may be opened and closed independently.

The high-pressure substrate processing apparatus 100 may further include a fastening module 150 for fastening the outer housing 121 and the outer door 125 in the closed state. Since the inner door 115 is supported on the outer door 125 by the support member 119, the fastening module 150 is configured such that the inner door 115 is also in close contact with the inner housing. The fastening module 150 maintains the protection gas at the second pressure within the outer chamber 120. The fastening module 150 also exerts a fastening force to maintain the reaction gas at the first pressure within the inner chamber 110.

Specifically, the fastening module 150 may include a support protrusion 151 and a locking protrusion 155.

The support protrusion 151 is a protrusion installed on the outer housing 121. As in the present embodiment, the support protrusion 151 may be installed on an inner peripheral surface of the outer housing 121. The plurality of support protrusions 151 may be disposed along the inner peripheral surface of the outer housing 121. The plurality of support protrusions 151 may be disposed on the same level or plane along the elevation direction E.

The locking protrusion 155 is sized to pass between a pair of adjacent support protrusions 151 when the outer door 125 moves in the elevation direction E. The locking protrusion 155 may be provided in multiple numbers, like the support protrusion 151. The locking protrusion 155 is configured to move relative to the outer door 125 in the closed state and be disposed on the support protrusion 151.

According to the present embodiment, the locking protrusion 155 may move while connected to the outer door 125. For example, the locking protrusion 155 may be rotatably installed on the outer door 125.

Alternatively, the locking protrusion 155 may also be movably installed on the outer housing 121. The locking protrusion 155 moves from the outer housing 121 toward the outer door 125 and is coupled with the outer door 125. To this end, the outer door 125 may have a groove-like structure (not illustrated) that accommodates the locking protrusion 155.

When the locking protrusion 155 is disposed on the support protrusion 151 depending on the movement, the locking protrusion 155 may be supported by the support protrusion 151 (fastened state). Accordingly, even under the high pressure of the process gas, the outer door 125 may remain firmly fastened to the outer housing 121.

When the plurality of locking protrusions 155 are provided, the plurality of locking protrusions 155 may rotate individually. Alternatively, the locking protrusions 155 may be integrated with a rotary member 157 and rotate together with the rotary member 157. The rotary member 157 may have a ring shape, as illustrated. In this embodiment, the rotary member 157 may be referred to as the rotating ring. The locking protrusion 155 may be configured to protrude outward from an outer peripheral surface of the rotating ring 157. The rotating ring 157 may be disposed to rotate along a rotational direction R (around a rotational axis along the elevation direction E).

The rotating ring 157 may be rotatably coupled to the outer door 125. The outer door 125 has an upper plate 126, and the rotating ring 157 (and a locking protrusion 155} may be disposed below the upper plate 126. When the outer door 125 also has a lower plate 127, the rotating ring 157 may be disposed between the plates 126 and 127. A bearing 159 may be disposed between each of the upper plate 126 and the lower plate 127 and the rotating ring 157. A thrust bearing may be used as the bearing 159. The rotating ring 157 may also be disposed within an area defined by the outer housing 121 (and the support protrusion 151).

The upper plate 126 is disposed to contact the outer housing 121 in the closed state. The upper plate 126 and the lower plate 127 may be connected by a spacer 128. As a result, the lower plate 127 may be disposed at a different level from the upper plate 126. The spacer 128 may have a smaller diameter or width than the upper plate 126 and/or the lower plate 127. The spacer 128 may be formed as a separate member from the upper plate 126 and the lower plate 127, or may form a single member with one of the upper plate 126 and the lower plate 127. The rotating ring 157, and furthermore, the locking protrusion 155, are disposed in the space secured by the spacer 128. The rotating ring 157 may be disposed substantially parallel to the outer door 125 while the spacer 128 is inserted into a hollow portion of the rotating ring 157.

While the rotating ring 157 rotates in the closed state, the outer door 125 may not be linked to the rotation of the rotating ring 157. In other words, while the upper plate 126 maintains the contact with the outer housing 121 via the seal member 129, the rotating ring 157 may rotate independently of the contact state. The seal member 129 may be an O-ring installed on an upper surface of the upper plate 126.

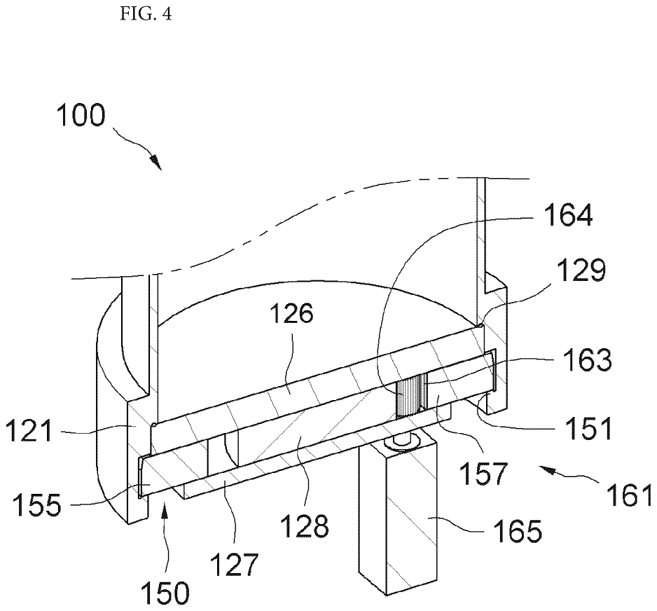

The configuration for driving the rotating ring 157 will be described with reference to FIG. 4. FIG. 4 is a cutaway perspective view illustrating a configuration for driving the rotating ring 157 of FIG. 3.

Referring further to this drawing, the rotating ring 157 may be driven for rotation by a drive unit 161.

The drive unit 161 may have a driven gear 163, a driving gear 164, and a motor 165. The driven gear 163 may be provided on an inner peripheral surface of the rotating ring 157. The driving gear 164 may be a gear that meshes with the driven gear 163. The driving gear 164 may be disposed between the rotating ring 157 and the spacer 128.

According to this configuration, the rotational power of the motor 165 is transmitted to the driving gear 164. A transmission shaft connecting an output shaft of the motor 165 and the driving gear 164 may be disposed to penetrate through the lower plate 127. As the driving gear 164 rotates, the driven gear 163 meshing with the driving gear 164 also rotates. As the driven gear 163 also rotates, the rotating ring 157 rotates, and thus the locking protrusion 155 also rotates along the rotational direction R (see FIG. 2). The locking protrusion 155 may move onto the support protrusion 151 or move to a position misaligned from the support protrusion 151, depending on its rotation.

During the process of rotating the locking protrusion 155, the outer door 125 does not rotate together with the locking protrusion 155. The power required to be output from the motor 165 may be sufficient at a level that rotates the locking protrusion 155, excluding the outer door 125.

While the drive unit 161 has been described as including the gears 163 and 164 and the motor 165, the present disclosure is not limited thereto. The drive unit may also be configured using other actuators, such as a cylinder.

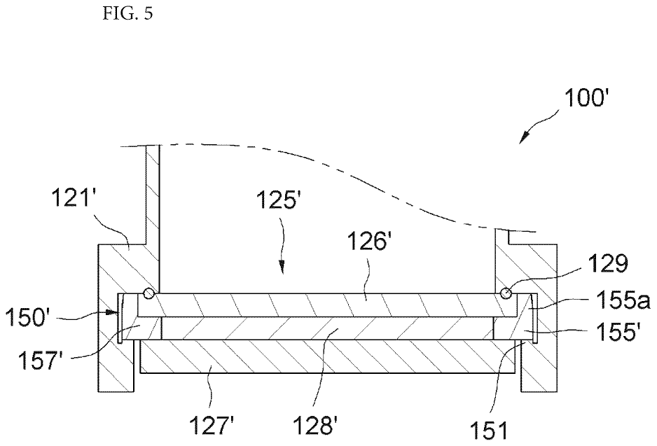

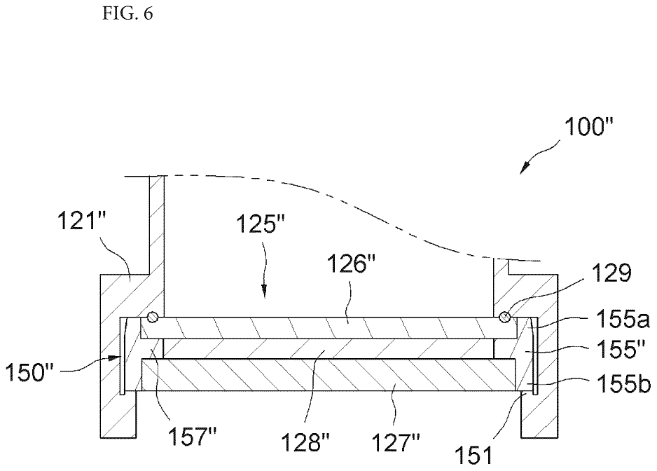

Other configurations of the high-pressure substrate processing apparatus 100 will be described with reference to FIGS. 5 and 6. FIG. 5 is a cross-sectional view illustrating a main portion of a high-pressure substrate processing apparatus 100′ according to one modified example of the high-pressure substrate processing apparatus 100 of FIG. 3, and FIG. 6 is a cross-sectional view illustrating a main portion of a high-pressure substrate processing apparatus 100″ according to another modified example of the high-pressure substrate processing apparatus 100 of FIG. 3. In these drawings, the same components as those of FIG. 3 are assigned the same reference numerals, and the bearing 159 is omitted for simplicity of the drawing.

Referring to FIG. 5, a locking protrusion 155′ further has an additional upper portion 155a, unlike the above-described locking protrusion 155. The upper portion 155a may be a portion disposed to correspond to a side surface of an upper plate 126′.

An upper surface of the upper portion 155a may be approximately at the same level as an upper surface of the upper plate 126′. Accordingly, an upper surface of the locking protrusion 155′ may contact an outer housing 121′, and a lower surface of the locking protrusion 155′ may contact the support protrusion 151.

Referring to FIG. 6, unlike the above-described locking protrusion 155, a locking protrusion 155″ further includes an upper portion 155a and a lower portion 155b. The upper portion 155a may be a portion disposed to correspond to a side surface of an upper plate 126′. The lower portion 155b may be a portion disposed to correspond to a side surface of the lower plate 127′.

An upper surface of the upper portion 155a may be approximately at the same level as an upper surface of the upper plate 126′. A lower surface of the lower portion 155b may be approximately at the same level as a lower surface of the lower plate 127′. Accordingly, an upper surface of the locking protrusion 155″ may contact an outer housing 121″, and a lower surface of the locking protrusion 155″ may contact the support protrusion 151.

In order to drive the rotation of the rotating ring 157′ and 157″, the drive unit 161 described above with reference to FIG. 4 may also be applied to the present modified examples.

In an alternative embodiment, a rotary disk (not illustrated) may be adopted instead of the rotating rings 157, 157′, and 157″ as the rotary member. The rotary disk is a solid disk, and may be rotatably connected to the bottom surface of the upper plate 126, 126′, and 126″. For this connection, a recessed portion may be formed in one of the rotating disk or the upper plates 126, 126′, and 126″ to accommodate a protrusion of the other. The bearing may be disposed between the protrusion and the recessed portion. The ring gear may be installed on the bottom surface of the rotating disk and may be rotatably driven by a motor and a pinion gear.

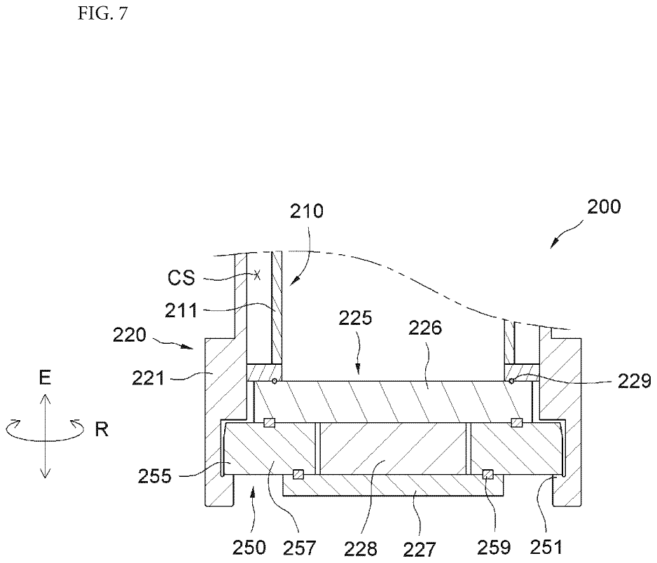

The above-described fastening module 150, 150′, and 150″ may also be applied to a semi-dual chamber, which is somewhat different from a dual chamber described above. This will be described with reference to FIG. 7, which illustrates an example in which the fastening module is applied to the semi-dual chamber. FIG. 7 is a cross-sectional view illustrating a closed state of a high-pressure substrate processing apparatus 200 according to another embodiment of the present disclosure. Similar reference numerals are given to the same components as in the above-described embodiment, and a detailed description thereof will be omitted.

Referring to this drawing, the semi-dual chamber may have two housings (an inner housing 211 and an outer housing 221) and one door 225. The two housings 211 and 221 may correspond to the inner housing and outer housing 121 of the above-described embodiment. The two housings 211 and 221 may be connected by their own shapes or by intervening with a separate member to form a closed space (CS, corresponding to the protection space). Similar to the above-described embodiment, the substrate and the reaction gas may be introduced into the inner housing 211. The inner housing 211 may also be protected by the protection gas injected into the closed space (CS). Unlike the above-described embodiments, the door 225 is not protected by the protection gas.

The door 225 may correspond to the outer door 125 of the above-described embodiments. The door 225 may open and close the inner housing 211. A fastening module 250 is applied to the outer housing 221 and the door 225. The specific configuration of the fastening module 250 may be substantially the same as the above-described fastening modules 150, 150′, and 150″.

In the present specification, the high-pressure substrate processing apparatuses 100, 100′, 100″, and 200 having the dual chamber and the semi-dual chamber has been described by way of example; however, the present disclosure is not limited thereto. A processing apparatus with a single chamber is also within the scope of the present disclosure. The single chamber includes one housing and one door. A wafer substrate is disposed within the chamber, and the process gas, specifically the reaction gas, for processing the wafer substrate is supplied. The fastening modules 150, 150′, 150″, and 250 may be applied to the single chamber as well. The fastening modules 150, 150′, 150″, and 250 allow the door to be firmly fastened to the housing even against the gas pressure.

While the present specification exemplifies a batch-type processing apparatus, the present disclosure is not limited thereto. The present disclosure may also be applied to a single wafer type processing apparatus.

### INDUSTRIAL APPLICABILITY

The present disclosure has industrial applicability in the field of manufacturing the high-pressure substrate processing apparatus.

1. A high-pressure processing apparatus, comprising:
an inner chamber configured to accommodate a substrate to be processed and a reaction gas supplied at a first pressure higher than atmospheric pressure;
an outer chamber including an outer housing that accommodates the inner chamber, and an outer door configured to move between a closed state in which the outer housing is closed and an opened state in which the outer housing is opened, and configured to accommodate a protection gas supplied at a second pressure that is set relative to the first pressure; and
a fastening module including a support protrusion installed on the outer housing, a rotary member rotatably installed on the outer door, and a locking protrusion protruding from the rotary member and disposed on the support protrusion as the rotary member rotates while the outer door is in the closed state.

2. The high-pressure processing apparatus of claim 1, wherein the rotary member is disposed within an area defined by the outer housing.

3. The high-pressure processing apparatus of claim 1, wherein the rotary member includes a rotating ring having a ring shape.

4. A high-pressure processing apparatus, comprising:
an inner chamber configured to accommodate a substrate to be processed and a reaction gas supplied at a first pressure higher than atmospheric pressure;
an outer chamber including an outer housing that accommodates the inner chamber, and an outer door configured to move between a closed state in which the outer housing is closed and an opened state in which the outer housing is opened, and configured to accommodate a protection gas supplied at a second pressure that is set relative to the first pressure; and
a fastening module including a support protrusion installed on the outer housing and a locking protrusion disposed on the support protrusion while being connected to the outer door as the locking protrusion moves in the closed state,
wherein the outer door includes an upper plate that contacts the outer housing in the closed state, and
the locking protrusion is disposed below the upper plate.

5. The high-pressure processing apparatus of claim 4, wherein the outer door further includes a lower plate disposed at a different level from the upper plate, and
the locking protrusion is disposed between the upper plate and the lower plate.

6. The high-pressure processing apparatus of claim 5, wherein the locking protrusion includes one of:
an upper portion disposed to correspond to a side surface of the upper plate; and
a lower portion disposed to correspond to a side surface of the lower plate.

7. The high-pressure processing apparatus of claim 1, wherein the outer door further includes a seal member that contacts the outer housing in the closed state, and
the locking protrusion is configured to rotate independently of contact between the seal member and the outer housing.

8. The high-pressure processing apparatus of claim 1, wherein the fastening module further includes a drive unit configured to rotate the locking protrusion.

9. The high-pressure processing apparatus of claim 8, wherein the fastening module further includes a rotary member having the locking protrusion formed thereon, and
the drive unit is configured to rotate the rotary member around a rotational axis extending along an opening/closing direction of the outer door.

10. The high-pressure processing apparatus of claim 9, wherein the drive unit includes:
a driven gear provided on the rotary member;
a driving gear meshing with the driven gear; and
a motor rotating the driving gear.

11. A high-pressure processing apparatus, comprising:
a chamber including a housing configured to accommodate a substrate to be processed and a process gas supplied at a pressure higher than atmospheric pressure, and a door configured to move between a closed state in which the housing is closed and an opened state in which the housing is opened;
a fastening module including a support protrusion installed on the housing and a locking protrusion disposed on the support protrusion while being connected to the door as the locking protrusion moves in the closed state,
wherein the door includes an upper plate that contacts the housing in the closed state, and
the locking protrusion is disposed below the upper plate.

12. The high-pressure processing apparatus of claim 11, wherein the door further includes a lower plate disposed at a different level from the upper plate, and
the locking protrusion is disposed between the upper plate and the lower plate.

13. The high-pressure processing apparatus of claim 11, wherein the fastening module further includes a rotary member that is rotatably installed on the door and has the locking protrusion protruding therefrom, and
the locking protrusion is supported by the support protrusion as the rotary member rotates.

14. The high-pressure processing apparatus of claim 11, wherein the door further includes a seal member installed on the upper plate, and
the locking protrusion is configured to move independently of contact between the housing and the seal member in the closed state.

15. The high-pressure processing apparatus of claim 11, wherein the process gas includes a reaction gas containing an active gas and a protection gas that is an inert gas, and
the housing includes:
an inner housing configured to accommodate the substrate to be processed and the reaction gas; and
an outer housing that accommodates the inner housing and coupled to the inner housing to form a closed space that accommodates the protection gas together with the inner housing, and
the door is configured to close the inner housing.
